(19) United States
(12) Patent Application Publication
(10) Pub. No.: US 2008/0254554 A1
(43) Pub. Date: Oct. 16, 2008

(54) METHOD FOR PRODUCING OPTICAL COUPLING ELEMENT

(76) Inventor: Takeshi KITAMURA, Nara (JP)

Correspondence Address: BIRCH STEWART KOLASCH & BIRCH, PO BOX 747, FALLS CHURCH, VA, 22040-0747, US

(21) Appl. No.: 12/099,830

(22) Filed: Apr. 9, 2008

(30) Foreign Application Priority Data
Apr. 11, 2007 (JP) 2007-104189

(51) Int. Cl. H01L 33/00; H01L 31/18

(52) U.S. Cl. 438/7; 257/E33.077; 257/E31.095

(57) ABSTRACT

A method for producing an optical coupling element of the present invention includes the steps of: determining the mounting position of a light-emitting element and a light-receiving element on the front surface of the header portion of each lead frame based on the current amplification factor of the light-receiving element to be mounted; determining the bending angle of each header portion and a distance between the two elements after being bent by calculation such that a predetermined current transfer ratio and an internal insulation distance required by the optical coupling element to be produced are obtained; detecting the determined mounting position by detecting intersections of V-shaped grooves in a grid pattern formed on the front surface of each header portion; mounting each element onto the detected position of the front surface of each header portion while detecting the concave-convex shape; and bending each header portion after mounting each element at the bending angle determined by calculation.

### BACKGROUND OF THE INVENTION

This application claims priority under 35 U.S.C. §119(a) on Patent Application No. 2007-104189 filed in Japan on Apr. 11, 2007, the entire contents of which are hereby incorporated herein.

The present invention relates to a method for producing an optical coupling element that transmits signals by a light-emitting element and a light-receiving element, and more particularly to a method for producing an optical coupling element that can secure a predetermined internal insulation distance.

Generally, the current transfer ratio, which is the ratio of input forward current and output current, is a main property of optical coupling elements. This CTR value is required to fall within a predetermined range wherever possible in designing a circuit in which the optical coupling element is incorporated.

Also, the internal insulation distance is an important indicator to determine the insulation property of an insulation type optical coupling element. Generally, the internal insulation distance refers to the shortest distance between the light-emitting side and the light-receiving side, which are insulated from each other with resin, and is required to be equal to or greater than a predetermined distance, depending on the insulation class. It is therefore very important to establish a production process that secures an internal insulation distance and a CTR value that are equal to or greater than a predetermined level.

In view of the above, methods for producing an optical coupling element that reduce variations of the CTR have been proposed.

For example, the production method described in JP H5-136454A is designed to eliminate misalignment between a light-emitting element and a light-receiving element by forming a concave portion in a package, applying a three-dimensional metal wiring to the concave portion to omit a lead frame, mounting a single chip on the three-dimensional metal wiring, and cutting the chip into a light-emitting element and a light-receiving element by dicing.

This production method yields an optical coupling element having a special structure, and thus it cannot be applied to a conventionally used production method in which a light-emitting element and a light-receiving element are mounted on the header portions of a light-emitting side lead frame and a light-receiving side lead frame, respectively, primary molding is performed for these header portions with these elements disposed facing each other, and secondary molding is performed to produce a packaged optical coupling element. For this reason, the above method has the problem of lack of versatility.

Meanwhile, as a method for suppressing process variations in CTR in the commonly used production method described above, a method (hereinafter referred to as Conventional Technology 1) has been proposed in which a mark to guide an element when mounting the element is provided, by processing, on the front surface of the header portion of a light-emitting side lead frame and that of a light-receiving side lead frame, and the elements are adjusted to be mounted in the marked positions, thereby suppressing process variations in CTR.

However, the method of Conventional Technology 1 described above has the problem that even if a light-receiving element and a light-emitting element are mounted in the marked positions with good accuracy, when the CTR of the produced optical coupling element is different from the desired CTR, it is necessary to provide an additional mark at another position of the front surface of the header portion of the lead frames by processing, in order to remount the elements in a different location, which requires additional labor and time. Further, in the case of fixing the mounting position, it is generally necessary to introduce several current amplification factor (hfe) ranks of the light-receiving element in order to obtain several different CTR ranks, but when the current amplification factor (hfe) varies, the output properties also vary.

Particularly, response property, which is one of the important properties of optical coupling elements, is easily affected by current amplification factors (hfe), and thus there has been the problem that a variation easily occurs in the response property of an optical coupling element obtained by introducing different current amplification factor (hfe) ranks.

### SUMMARY OF THE INVENTION

The present invention has been conceived to solve the above problems, and it is an object of the present invention to provide a method for producing an optical coupling element that can suppress the process variations of CTR of the optical coupling element and can secure an internal insulation distance equal to or greater than a predetermined distance.

In order to solve the above problems, a method for producing an optical coupling element of the present invention is a method for producing an optical coupling element that transmits signals by a light-emitting element and a light-receiving element, the method comprising the steps of forming a concave-convex shape on a front surface of each header portion of a light-emitting side lead frame and a light-receiving side lead frame so that a plurality of positions on the front surface of the header portion can be detected; determining a mounting position of the light-emitting element and the light-receiving element on the each header portion based on a current amplification factor of the light-receiving element to be mounted; determining a bending angle of each header portion of the lead frames and a distance between the light-emitting and light-receiving elements after being bent by calculation such that a predetermined current transfer ratio and an internal insulation distance required by the optical coupling element to be produced are obtained; detecting the determined mounting position by detecting the concave-convex shape on the front surface of each header portion of the lead frames; mounting each element onto the detected position on the front surface of the each header portion while detecting the concave-convex shape; and bending the header portions after mounting the elements at the bending angles determined by calculation.

Here, as the concave-convex shape, by providing linear grooves formed in a grid pattern as the concave portions, a concave-convex shape in a grid pattern (i.e., check pattern) as a whole can be obtained. Alternatively, by providing linear protrusions formed in a grid pattern as the convex portions, the concave-convex shape in a grid pattern (i.e., check pattern) as a whole can be obtained. By providing a concave-convex shape as described above, a configuration is attained in which a plurality of intersections at which the grooves or protrusions intersect each other are arranged at a predetermined spacing along two directions: one direction of the front surface of the header portion and the other direction orthogonal to the one direction. Accordingly, by detecting the position of an intersection, a specific position on the front surface of the header portion can be determined accurately. In other words, it is possible to accurately determine the mounting position of the element and to mount the element centered on the intersection with good accuracy.

The grooves and protrusions described above need not form a continuous grid pattern shape, and may form a shape in which the position of each intersection of the grid pattern can be determined accurately. For example, a configuration may be adopted in which a plurality of conical concave portions or convex portions are arranged at a predetermined spacing along two directions: one direction on the front surface of the header portion and the other direction orthogonal to the one direction. In this case, the concave portions or convex portions correspond to the intersections described above, and thus by detecting the position of a concave portion or convex portion, a specific position on the front surface of the header portion can be determined accurately. In other words, it is possible to accurately determine the mounting position of the element, and to mount the element centered on the concave portion or the convex portion with good accuracy.

In the method for producing an optical coupling element of the present invention that uses the lead frames configured as described above, first, the mounting position of the light-emitting element and the light-receiving element on each header potion is determined based on the current amplification factor of the light-receiving element to be mounted. Subsequently, the bending angle of the header portion of each lead frame and the distance between the two elements after being bent are determined by calculation such that predetermined current transfer ratio and internal insulation distance required by the optical coupling element to be produced are obtained.

Then, by detecting the concave-convex shape of the front surface of the header portion of each lead frame, the mounting position determined by calculation in the above step is detected. In this case, as described above, the position of each intersection of the concave-convex shape is easily obtained by calculation, it is easy to detect the intersection located in (or nearest) the determined mounting position by image processing or the like.

Then, while detecting the concave-convex shape, a silver paste is die-bonded centered on the intersection. Subsequently, while detecting the concave-convex shape, the element is mounted (die-bonded) such that the center of the circle of the die-bonded silver paste is aligned with the center of the element. In this manner, the element can be mounted almost exactly on the determined mounting position (on the intersection) of the front surface of the header portion.

After that, the lead frames on which the elements 1 and 2 are mounted, respectively, are disposed horizontally with a predetermined spacing therebetween such that the header portions of the lead frames face each other, and are then bent at the bending angles determined by the calculation above. This completes the arrangement of the light-emitting element and the light-receiving element having desired CTR value and internal insulation distance. In this state, by performing primary molding using a light-transmitting resin, and then secondary molding using a light-shielding resin, an optical coupling element having the desired CTR value and internal insulation distance can be produced.

As described above, according to the method for producing an optical coupling element of the present invention, by forming a concave-convex shape in a grid pattern in the front surface of the header portion, the position of each intersection is clearly found from spatial coordinates, the mounting position of each element can be determined accurately, and thus it is possible to mathematically calculate the internal insulation distance. With this, the optimization of CTR can be performed focusing only on the assembly conditions having an internal insulation distance equal to or greater than a predetermined distance, and it is therefore possible to omit unnecessary assembly conditions, and to suppress the variation of CTR. Also, by changing the mounting position of the light-receiving element and the light-emitting element on the front surface of the header portion, the relative position of the light-receiving element and the light-emitting element changes, and the CTR also changes. Accordingly, the need to prepare light-receiving elements of various current amplification factor (hfe) ranks so as to comply with various CTR ranks is eliminated, and thus it is possible to reduce the number of components and the inventory, as well as the variation of output properties.

### BRIEF DESCRIPTION OF THE DRAWINGS

FIG. 1 is a cross-sectional view that shows the structure of an optical coupling element obtained by applying a production method of the present invention.

FIG. 2A is a plan view that shows a light-emitting element mounted on the front surface of the header portion of a lead frame for light-emitting element, and FIG. 2B is a plan view that shows a light-receiving element mounted on the front surface of the header portion of a lead frame for light-receiving element.

FIGS. 3A and 3B show an example of the structure of a primary transfer molding resin molding die (hereinafter simply referred to as “resin molding die”) used to perform a bending step. FIG. 3A is a cross-sectional view that shows a state before bending, and FIG. 3B is a cross-sectional view that shows a state after bending.

FIG. 4A is a partially enlarged cross-sectional view that shows an example of a concave-convex shape, and FIG. 4B is a partially enlarged view that shows another example of a concave-convex shape.

### DETAILED DESCRIPTION OF PREFERRED EXAMPLES

Hereinafter, an embodiment of the present invention will be described with reference to the accompanying drawings.

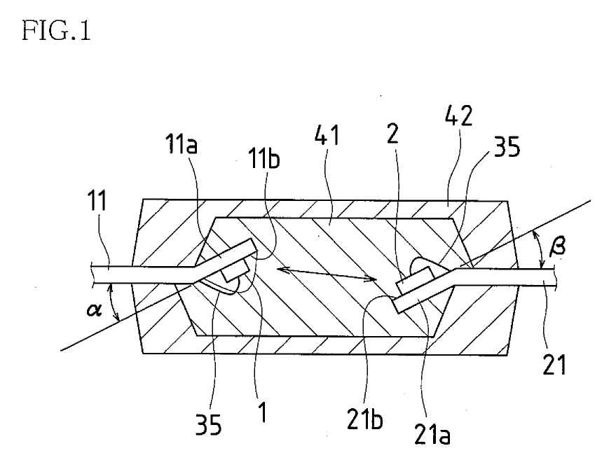

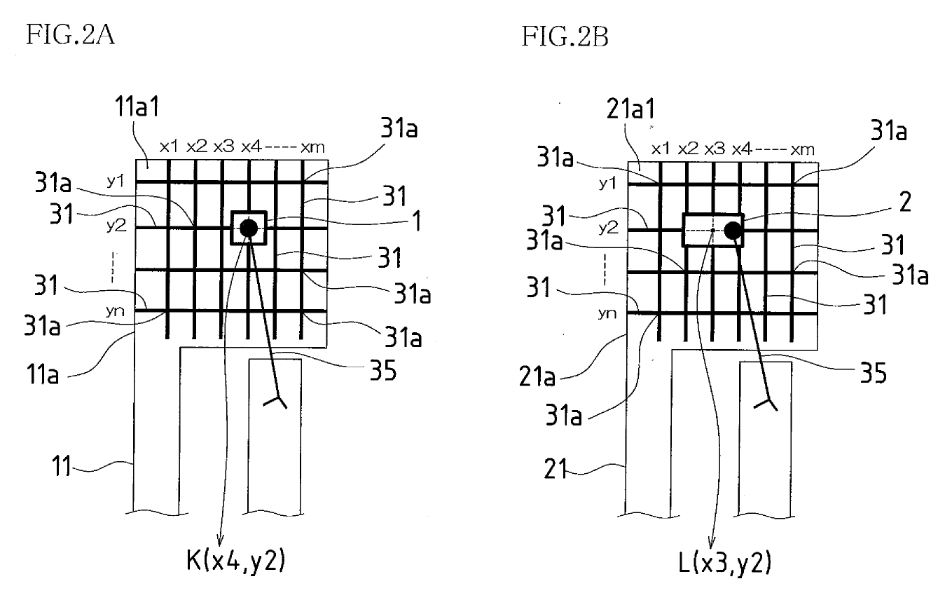

FIG. 1 is a cross-sectional view that shows the structure of an optical coupling element obtained by applying a production method of the present invention. FIG. 2A is a plan view that shows a light-emitting element mounted on the front surface of the header portion of a lead frame for a light-emitting element, and FIG. 2B is a plan view that shows a light-receiving element mounted on the front surface of the header portion of a lead frame for a light-receiving element.

The optical coupling element of the present embodiment has a structure formed as follows. A light-emitting element 1 is mounted onto a front surface 11b of a header portion 11a of a light-emitting side lead frame 11, and a light-receiving element 2 is mounted onto a front surface 21b of a header portion 21a of a light-receiving side lead frame 21. After that, the light-emitting element 1 and the light-receiving element 2 are connected to the respective lead portions with wires 35. Then, the header portion 11a of the light-emitting side lead frame 11 on which the light-emitting element 1 is mounted, and the header portion 21a of the light-receiving side lead frame 21 on which the light-receiving element 2 is mounted are bent at predetermined bending angles. With the light-emitting element 1 and the light-receiving element 2 obliquely facing each other, the header portion 11a of the light-emitting element 1 and the header portion 21a of the light-receiving element 2 are entirely covered with a light-transmitting primary molding resin 41. Further, the primary molding resin 41 is covered with a light-shielding secondary molding resin 42.

The front surface 11b of the header portion of the light-emitting lead frame 11 and the front surface 21b of the header portion of the light-receiving lead frame 21 are provided with a concave-convex shape as shown in FIGS. 2A and 23 so that a plurality of positions on the front surface of the header portion can be detected. Specifically, m (six in this example) V-shaped grooves 31, 31, . . . are formed along one direction (the X-axis direction in FIGS. 2A and 2B) of the front surface of the header portion, and n (four in this example) V-shaped grooves 31, 31, . . . are formed along another direction (the Y-axis direction in FIGS. 2A and 2B) orthogonal to the X-axis direction. In other words, a plurality of V-shaped grooves 31, 31, . . . are formed at a predetermined spacing along the X-axis direction and the Y-axis direction, forming a grid pattern. This provides a configuration in which a plurality of intersections 31a, 31a, at which the V-shaped grooves 31, 31, . . . formed in a grid pattern intersect each other are arranged at a predetermined spacing along the X-axis and the Y-axis of the front surface of the header portion.

Here, the V-shaped grooves formed along the X-axis are represented by x1, x2, . . . xm, and the V-shaped grooves formed along the Y-axis are represented by y1, y2, . . . yn. For the sake of simplicity, the intersections 31a, 31a, . . . of the V-shaped grooves formed in the front surface 11b of the header portion on which the light-emitting element 1 is mounted are represented by coordinates K(m, n), and the intersections 31a, 31a, . . . of the V-shaped grooves formed in the front surface 21b of the header portion on which the light-receiving element 2 is mounted are represented by coordinates L(m, n).

As described above, in the present embodiment, the intersections 31a are arranged at a predetermined spacing in the front surface of the header portion, and therefore by detecting the position (i.e., coordinates) of an intersection 31a, a specific position on the front surface of the header portion can be determined accurately. In other words, it is possible to accurately determine the mounting position (positional coordinates) of the light-emitting element 1 and the light-receiving element 2, as well as to mount the element centered on a determined intersection 31a with good accuracy.

Next, a method for producing an optical coupling element by using the lead frames 11 and 21 configured as described above will be described.

Here, the current amplification factor (hfe) rank of the light-receiving element 2 to be mounted is assumed to have already been determined. In the first step, in consideration of the current amplification factor (hfe) of the light-receiving element 2, the mounting positions of the light-emitting element 1 and the light-receiving element 2 on the header portions 11a and 21a that are suitable for producing an optical coupling element of a desired CTR rank are determined. The mounting positions can be determined by the coordinates K(m, n), L(m, n) of the above-described intersections.

For example, in FIG. 2, the mounting position of the light-emitting element 1 is determined to be at the coordinates K(x4, y2), and the mounting position of the light-receiving element 2 is determined to be at the coordinates L(x3, y2). In this manner, according to the present invention, an optimal mounting position for each of the light-emitting element 1 and the light-receiving element 2 (particularly, the mounting position of the light-receiving element 2) can be determined in advance according to the current amplification factor (hfe) rank of the light-receiving element 2 to be used. Also, even when the CTR rank of an optical coupling element to be produced is changed, by adjusting the mounting position of each element, it is possible to comply with the changed CTR rank while using a light-receiving element of the same current amplification factor (hfe) rank. Accordingly, the need to prepare light-receiving elements of various current amplification factor (hfe) ranks in advance so as to comply with various CTR ranks is eliminated, and thus it is possible to reduce the number of components and the inventory.

After the mounting positions are determined in the above-described manner, in the next step, the bending angles of the header portion 11a of the light-emitting side lead frame 11 and the header portion 21a of the light-receiving side lead frame 21 are determined by calculation such that the desired CTR value and the internal insulation distance T0 required by the optical coupling element to be produced are obtained. In other words, various CRT values can be obtained by parametrically changing the intersection (the coordinates K(x4, y2)) of the light-emitting element 1 and the intersection (the coordinates L(x3, y2)) of the light-receiving element 2 determined above, as well as α and β, where α is the bending angle of the header portion 11a of the light-emitting side lead frame 11, and β is the bending angle of the header portion 21a of the light-receiving side lead frame 21 (α and β can take on negative values as well). Accordingly, when the CTR value is set to a desired value, the mounting positions of the light-emitting element 1 and the light-receiving element 2 are determined, so the bending angles α and β of the header portions can be determined. In other words, assembly conditions closest to desired CRT value and internal insulation distance T0 can be determined.

After the assembly conditions are determined in the above-described manner, in the next step, by detecting the concave-convex shape of the front surface 11b of the header portion of the light-emitting side lead frame 11, that is, the intersections 31a, the mounting position (intersection 31a) of the front surface 11b of the header portion represented by the coordinates K(x4, y2) determined by calculation is detected. In this case, as described above, the position of each intersection of the concave-convex shape is easily determined by calculation, and thus the intersection located in (or nearest) the determined mounting position can be detected by image processing or the like. Because such a detection method using image processing or the like is conventionally known, a detailed description thereof is omitted here. Similarly, by detecting the concave-convex shape of the front surface 21b of the header portion of the light-receiving side lead frame 21, that is, the intersections 31a, the mounting position (intersection 31a) of the front surface 21b of the header portion represented by the coordinates L(x3, y2) determined by calculation is detected.

In the next step, for each of the light-emitting element 1 and the light-receiving element 2, while detecting the concave-convex shape, a silver paste is die-bonded centered on the intersection 31a determined to be the mounting position. Then, while detecting the concave-convex shape, the elements 1 and 2 are mounted (die-bonded) such that the center of the circle of the die-bonded silver paste is aligned with the center of the light-emitting element 1 or the light-receiving element 2. In this manner, the light-emitting element 1 and the light-receiving element 2 can be mounted virtually exactly on the determined mounting position (on the intersection) of the front surface of the header portion.

In the next step, the lead frames 11 and 21 on which the elements 1 and 2 are mounted are disposed horizontally with a predetermined spacing there between such that the header portions 11a and 21a face each other. The predetermined spacing at this time is a spacing set such that the distance (shortest distance) between the two elements 1 and 2 after the header portions 11a and 21a are bent at angles α and β, respectively, equals the internal insulation distance T0. Then, with this arrangement, the header portions 11a and 21a are bent at the bending angles α and β determined by calculation, respectively.

This completes the arrangement of the light-emitting element 1 and the light-receiving element 2 having the desired CTR value and internal insulation distance T0. Subsequently, in this state, primary molding using a light-transmitting resin (primary molding resin 41) is performed, followed by secondary molding using a light-shielding resin (secondary molding resin 42), whereby an optical coupling element having desired CTR value and internal insulation distance as shown in FIG. 1 can be produced.

An example of the step of bending each header portion 11a, 21a will be described in detail in the following.

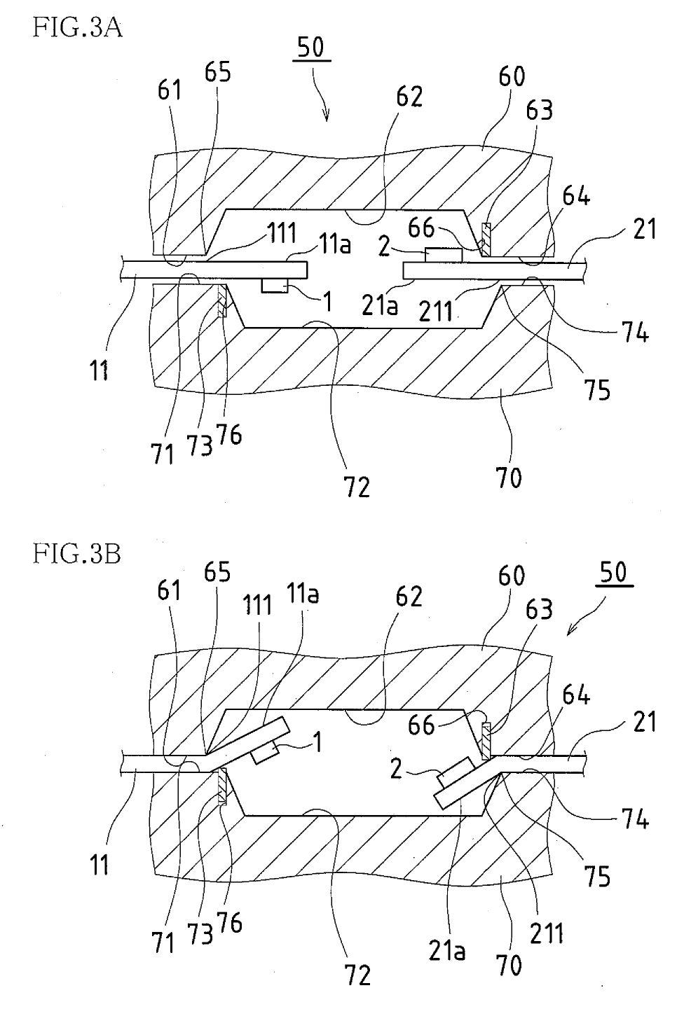

FIGS. 3A and 3B show an example of the structure of a primary transfer molding resin molding die (hereinafter simply referred to as “resin molding die”) used to perform the bending step. FIG. 3A is a cross-sectional view that shows a state before bending, and FIG. 3B is a cross-sectional view that shows a state after bending.

This resin molding die 50 is configured of an upper die 60 and a lower die 70. The contact face 71 of the lower die 70 for holding the light-emitting side lead frame 11 extends slightly inward (into the cavity space) beyond the contact face 61 of the upper die 60 that faces the contact face 71. In an end portion of the contact face 71, a bending pin 73 is provided such that the pin can be moved vertically from a cavity inner wall surface 72.

Likewise, the contact face 64 of the upper die 60 for holding the light-receiving side lead frame 21 extends slightly inward (into the cavity space) beyond the contact face 74 of the lower die 70 that faces the contact face 64. In an end portion of the contact face 64, a bending pin 63 is provided such that the pin can be moved vertically from a cavity inner wall surface 62.

In other words, the bending pin 73 is inserted into a slide hole 76 formed in the lower die 70, and can be slid vertically in the slide hole 76 by a not shown hydraulic cylinder or the like. Similarly, the bending pin 63 is inserted into a slide hole 66 formed in the upper die 60, and can be slid vertically in the slide hole 66 by a not shown hydraulic cylinder or the like.

Then, between the upper die 60 and the lower die 70 configured as described above, the unbent light-emitting side lead frame 11 on which the light-emitting element 1 is mounted and the unbent light-receiving side lead frame 21 on which the light-receiving element 2 is mounted are disposed on the right and left sides (see FIG. 3A). At this time, the frames are disposed such that a base end portion 111 of the header portion 11a of the light-emitting side lead frame 11 is aligned with an edge portion 65 of the contact face 61 of the upper die 60, and a base end portion 211 of the header portion 21a of the light-receiving side lead frame 21 is aligned with a edge portion 75 of the contact face 74 of the lower die 70. Also, the bending pins 63 and 73 are contained in the slide holes 66 and 76 of the upper die 60 and the lower die 70, respectively. In other words, the pins are not projected from the slide holes 66 and 76.

In this state, the two lead frames 11 and 21 are clamped (mold clamping) with the upper die 60 and the lower die 70. At this time, the bending pins 63 and 73 are not projected from the slide holes 66 and 76 as mentioned above, and thus a positional deviation of the lead frames 23 and 24 does not occur during clamping. Then, after clamping, the bending pin 63 of the upper die 60 is slid downward by a predetermined distance, and the bending pin 73 of the lower die 70 is slid upward by a predetermined distance.

In this manner, as shown in FIG. 3B, the header portion 11a of the light-emitting side lead frame 11 is forced to bend upward at the base end portion 111 of the header portion 11a supported by the edge portion 65 of the contact face 61 of the upper die 60 that acts as a fulcrum by the bending pin 73 projected from the lower die 70. Thereby, the header portion 11a is bent upward by a predetermined angle (α) Similarly, the header portion 21a the light-receiving side lead frame 21 is forced to bend downward at the base end portion 211 of the header portion 21a supported by the edge portion 75 of the contact face 74 of the lower die 70 that acts as a fulcrum by the bending pin 63 projected from the upper die 60. Thereby, the header portion 21a is bent downward by a predetermined angle (β).

Consequently, the light-emitting element 1 and the light-receiving element 2 are processed into a state in which they are disposed facing each other while maintaining a desired internal insulation distance T0 in the cavity space of the resin molding die 50. In other words, the lead frames 11 and 21 can be bent vertically in opposite directions during mold clamping for primary transfer molding with resin. Thereby, a reduction in the number of steps (the reduction of the step of bending each lead frame) can be achieved.

After that, primary transfer molding is performed to fill the cavity space with a light-transmitting resin (primary molding resin 41), followed by cooling, and the upper die 60 and the lower die 70 are then separated. This completes the primary transfer molding.

Although the specific example given above employs a configuration in which the header portions 11a and 21a are bent at one time by using the resin molding die 50, it is also possible to employ a configuration in which the bending of each header portion 11a, 21a and the primary transfer molding are performed separately. Specifically, for example, only the bending of each header portion 11a, 21a is performed in a separate step, and the bent lead frames 11 and 21 are placed in a resin molding die having a conventional structure, and then primary transfer molding is performed.

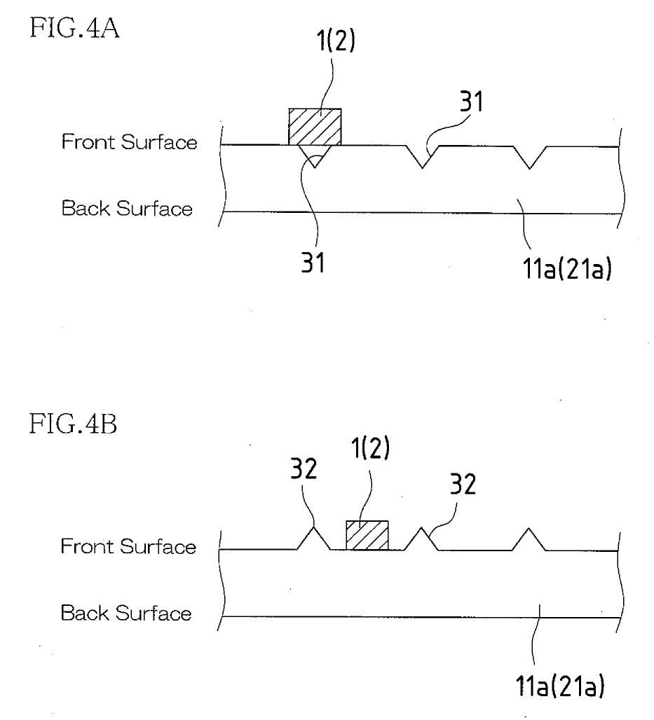

Also, in the above-described embodiment, as the concave-convex shape formed on the front surface of the header portion, the surface in which the V-shaped grooves 31 are formed is defined as the concave portion side, and the flat surface is defined as the convex portion side as shown in FIG. 4A. However, conversely, a concave-convex shape as shown in FIG. 4B may be employed in which the surface on which inverted V-shaped linear protrusions 32 are formed is defined as the convex portion side, and the flat surface is defined as the concave portion side. It should be noted that, in this case, the mounting position of the element is the center portion of a quadrangular area surrounded by the protrusions 32.

Also, the V-shaped grooves 31 and protrusions 32 need not form a continuous grid pattern shape, and they may be formed only on the intersections of a grid pattern. Specifically, a configuration may be adopted in which a plurality of conical concave grooves or convex portions are arranged at a predetermined spacing along two directions: one direction on the front surface of the header portion and the other direction orthogonal to that direction. In this case, the concave grooves or convex portions correspond to the intersection 31a, and thus by detecting the position of a concave groove or convex portion, a specific position on the front surface of the header portion can be determined accurately.

The present invention can be embodied and practiced in other different forms without departing from the gist and essential characteristics thereof. Therefore, the above-described embodiments are considered in all respects as illustrative and not restrictive. The scope of the invention is indicated by the appended claims rather than by the foregoing description. All variations and modifications falling within the scope of the appended claims are intended to be embraced therein.

1. A method for producing an optical coupling element that transmits signals by a light-emitting element and a light-receiving element, the method comprising the steps of:
forming a concave-convex shape on a front surface of each header portion of a light-emitting side lead frame and a light-receiving side lead frame so that a plurality of positions on the front surface of the header portion can be detected;
determining a mounting position of the light-emitting element and the light-receiving element on the each header portion based on a current amplification factor of the light-receiving element to be mounted;
determining a bending angle of each header portion of the lead frames and a distance between the light-emitting and light-receiving elements after being bent by calculation such that a predetermined current transfer ratio and an internal insulation distance required by the optical coupling element to be produced are obtained;
detecting the determined mounting position by detecting the concave-convex shape on the front surface of each header portion of the lead frames;
mounting each element onto the detected position on the front surface of the each header portion while detecting the concave-convex shape; and
bending the header portions after mounting the elements at the bending angles determined by calculation.

2. The method for producing an optical coupling element according to claim 1, further comprising,
after the step of bending the header portions, a step of primary molding the header portions including the light-emitting element and the light-receiving element entirely with a light-transmitting resin, and
a step of secondary molding the primary molding resin with a light-shielding resin.

3. The method for producing an optical coupling element according to claim 1, wherein concave portions of the concave-convex shape are linear grooves formed in a grid pattern.

4. The method for producing an optical coupling element according to claim 1, wherein convex portions of the concave-convex shape are linear protrusions formed in a grid pattern.

5. The method for producing an optical coupling element according to claim 1, wherein a plurality of the concave portions or convex portions of the concave-convex shape are arranged at a predetermined spacing along one direction on the front surface of the header portion and another direction orthogonal to the one direction.

6. The method for producing an optical coupling element according to claim 2, wherein concave portions of the concave-convex shape are linear grooves formed in a grid pattern.

7. The method for producing an optical coupling element according to claim 2, wherein convex portions of the concave-convex shape are linear protrusions formed in a grid pattern.

8. The method for producing an optical coupling element according to claim 2, wherein a plurality of the concave portions or convex portions of the concave-convex shape are arranged at a predetermined spacing along one direction on the front surface of the header portion and another direction orthogonal to the one direction.
